(19) United States
(12) Patent Application Publication
(10) Pub. No.: US 2007/0000539 A1
(43) Pub. Date: Jan. 4, 2007

(54) Compositions and use thereof in dye sensitized solar cells

(75) Inventors: John Yupeng Gui, Niskayuna, NY (US); Oltea Puica Siclovan, Rexford, NY (US); James Lawrence Spivack, Cobleskill, NY (US); Fuyou Li, Shanghai (CN); Xianghong Li, Shanghai (CN); Men Zhang, Shanghai (CN)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/171,713

(22) Filed: Jun. 30, 2005

(51) Int. Cl. H01L 31/00

(52) U.S. Cl. 136/263

(57) ABSTRACT

The present invention provides in one aspect a composition having at least one metal complex, such that the metal complex comprises at least one metal atom, a phenanthroline-based first ligand and a second ligand comprising at least one acidic group, and at least two coordinative nitrogen atoms capable of simultaneous binding to the metal atom. This composition may be disposed on a semiconductor layer which is further disposed on an electrically conductive surface to provide a dye-sensitized electrode. The dye-sensitized electrode can be assembled together with a counter electrode and a redox electrolyte to provide a dye-sensitized solar cell.

### BACKGROUND

The invention includes embodiments that relate to compositions comprising metal complexes. The invention also includes embodiments that relate to dye-sensitized electrodes and dye-sensitized solar cells that may be produced using the above composition.

The dyes or sensitizers are a key feature of the dye-sensitized solar cells (DSSC) that have great potential for future photovoltaic applications owing to their potentially low production cost. The central role of the dyes is the efficient absorption of light and its conversion to electrical energy. In order for the dyes to provide high efficiency, solar radiation over as broad a spectrum as possible has to be absorbed. Further, ideally, every absorbed photon should be converted to an electron resulting from an excited dye state. In order for the dye to be returned to its initial state, ready for absorption of another photon, it has to accept an electron from the hole transport material. To ensure many turnovers and a long useful life of the device, both electron injection into the electron transport material and hole injection into the hole transport material has to be faster than any other chemistry that the dye is subject to. Furthermore, it is important that the dyes do not recapture electrons injected into the electron transport material, or serve as an electronic pathway from the electron transport material to the hole transport material.

Particularly desirable would be dyes with high power efficiencies for applications in DSSCs. Organic dyes capable of absorbing a broad range of wavelengths in the solar spectrum as well as having strong absorptivity represent an attractive but elusive goal, since the light absorption characteristics of most organic materials cannot be predicted reliably and must be determined experimentally. Efforts to improve dye performance in DSSCs have focused on increasing the thickness of the TiO₂ film component on which the dye is adsorbed thereby increasing the surface area available for dye adsorption. However, as a result of increasing the TiO₂ film thickness in the DSSC, the transport distance for the photo-generated electron increases, thereby increasing the possibility of unproductive back reactions.

Therefore, there is a need for dyes that absorb radiation over a broad range of the solar spectrum and have strong absorptivity. Moreover, it is very desirable to provide energy efficient solar cells that can take advantage of dyes that can absorb over a broad range and have high absorptivity values.

### BRIEF DESCRIPTION

The present invention provides a composition comprising at least one metal complex, such that the metal complex comprises at least one metal atom, at least one first ligand and at least one second ligand. In one embodiment of the present invention, the first ligand has structure I: 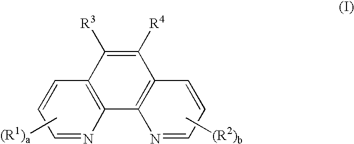
wherein a and b are independently integers from 0 to 3; R¹ and R² are independently at each occurrence a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical; R³ and R⁴ are independently a C₁-C₂₀ aliphatic radical, a C₃-C₄₀ aromatic radical, or a C₃-C₄₀ cycloaliphatic radical, wherein at least one of R³ and R⁴ comprises a nitrogen atom, or R³ and R⁴ together form a cycloaliphatic or aromatic radical comprising at least one nitrogen atom. The second ligand comprises at least one acidic group, and at least two coordinative nitrogen atoms capable of simultaneous binding to the metal atom.

In another embodiment, the present invention provides a dye-sensitized electrode comprising a substrate having an electrically conductive surface, a semiconductor layer disposed on the electrically conductive surface, and a composition having at least one metal complex described above.

In a further embodiment, the present invention provides a solar cell comprising a dye-sensitized electrode as described above, a counter electrode, and an electrolyte in contact with the dye-sensitized electrode and the counter electrode.

Various other features, aspects, and advantages of the present invention will become more apparent with reference to the following description and appended claims.

### BRIEF DESCRIPTION OF THE DRAWINGS

FIG. 1 presents a reaction scheme for the preparation of a first ligand used in the preparation of the metal complex dye compositions of the present invention.

FIG. 2 presents a reaction scheme for the preparation of the metal complex dye compositions of the present invention.

### DETAILED DESCRIPTION

In the following specification and the claims which follow, reference will be made to a number of terms which shall be defined to have the following meanings.

The singular forms “a”, “an” and “the” include plural referents unless the context clearly dictates otherwise.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆aromatic radical comprising a nitro group, the nitro group being a functional group. Aromatic radicals include halogenated aromatic radicals such as 4-trifluoromethylphenyl, hexafluoroisopropylidenebis(4-phen-1-yloxy) (i.e., —OPhC(CF₃)₂PhO—), 4-chloromethylphen-1-yl, 3-trifluorovinyl-2-thienyl, 3-trichloromethylphen-1-yl (i.e., 3-CCl₃Ph—), 4-(3-bromoprop-1-yl)phen-1-yl (i.e., 4-BrCH₂CH₂CH₂Ph—), and the like. Further examples of aromatic radicals include 4-allyloxyphen-1-oxy, 4-aminophen-1-yl (i.e., 4-H₂NPh—), 3-aminocarbonylphen-1-yl (i.e., NH₂COPh—), 4-benzoylphen-1-yl, dicyanomethylidenebis(4-phen-1-yloxy) (i.e., —OPhC(CN)₂PhO—), 3-methylphen-1-yl, methylenebis(4-phen-1-yloxy) (i.e., —OPhCH₂PhO—), 2-ethylphen-1-yl, phenylethenyl, 3-formyl-2-thienyl, 2-hexyl-5-furanyl, hexamethylene-1,6-bis(4-phen-1-yloxy) (i.e., —OPh(CH₂)₆PhO—), 4-hydroxymethylphen-1-yl (i.e., 4-HOCH₂Ph—), 4-mercaptomethylphen-1-yl (i.e., 4-HSCH₂Ph—), 4-methylthiophen-1-yl (i.e., 4-CH₃SPh—), 3-methoxyphen-1-yl, 2-methoxycarbonylphen-1-yloxy (e.g., methyl salicyl), 2-nitromethylphen-1-yl (i.e., 2-NO₂CH₂Ph), 3-trimethylsilylphen-1-yl, 4-t-butyldimethylsilylphenl-1-yl, 4-vinylphen-1-yl, vinylidenebis(phenyl), and the like. The term “a C₃-C₁₀ aromatic radical” includes aromatic radicals containing at least three but no more than 10 carbon atoms. The aromatic radical 1-imidazolyl(C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis(cyclohex-4-yl) (i.e., —C₆H₁₀C(CF₃)₂ C₆H₁₀—), 2-chloromethylcyclohex-1-yl, 3-difluoromethylenecyclohex-1-yl, 4-trichloromethylcyclohex-1-yloxy, 4-bromodichloromethylcyclohex-1-ylthio, 2-bromoethylcyclopent-1-yl, 2-bromopropylcyclohex-1-yloxy (e.g., CH₃CHBrCH₂C₆H₁₀—), and the like. Further examples of cycloaliphatic radicals include 4-allyloxycyclohex-1-yl, 4 aminocyclohex-1-yl (i.e., H₂NC₆H₁₀—), 4-aminocarbonylcyclopent-1-yl (i.e., NH₂COC₅H₈—), 4-acetyloxycyclohex-1-yl, 2,2-dicyanoisopropylidenebis(cyclohex-4-yloxy) (i.e., —OC₆H₁₀C(CN)₂C₆H₁₀O—), 3-methylcyclohex-1-yl, methylenebis(cyclohex-4-yloxy) (i.e., —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e., —OC₆H₁₀(CH₂)₆C₆H₁₀O—), 4-hydroxymethylcyclohex-1-yl (i.e., 4-HOCH₂C₆H₁₀—), 4-mercaptomethylcyclohex-1-yl (i.e., 4-HSCH₂C₆H₁₀—), 4-methylthiocyclohex-1-yl (i.e., 4-CH₃SC₆H₁₀—), 4-methoxycyclohex-1-yl, 2-methoxycarbonylcyclohex-1-yloxy(2-CH₃OCOC₆H₁₀O—), 4-nitromethylcyclohex-1-yl (i.e., NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g., (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl(C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g., —CH₂CHBrCH₂—), and the like. Further examples of aliphatic radicals include allyl, aminocarbonyl (i.e., —CONH₂), carbonyl, 2,2-dicyanoisopropylidene (i.e., —CH₂C(CN)₂CH₂—), methyl (i.e., —CH₃), methylene (i.e., —CH₂—), ethyl, ethylene, formyl (i.e., —CHO), hexyl, hexamethylene, hydroxymethyl (i.e., —CH₂OH), mercaptomethyl (i.e., —CH₂SH), methylthio (i.e., —SCH₃), methylthiomethyl (i.e., —CH₂SCH₃), methoxy, methoxycarbonyl (i.e., CH₃OCO—), nitromethyl (i.e., —CH₂NO₂), thiocarbonyl, trimethylsilyl (i.e., (CH₃)₃Si—), t-butyldimethylsilyl, 3-trimethyoxysilypropyl (i.e., (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e., CH₃—) is an example of a C₁ aliphatic radical. A decyl group (i.e., CH₃(CH2)₉—) is an example of a C₁₀ aliphatic radical.

As used herein, the term “electromagnetic radiation” means electromagnetic radiation having wavelength in the range from about 200 nm to about 2500 nm.

As noted, the present invention provides a composition comprising at least one metal complex, such that the metal complex comprises at least one metal atom, at least one first ligand, and at least one second ligand. In one embodiment of the present invention this composition is disposed on a semiconductor layer which is further disposed on an electrically conductive surface to provide a dye-sensitized electrode. The dye-sensitized electrode, when combined with a counter electrode and a redox electrolyte provides a dye-sensitized solar cell.

In one embodiment of the present invention the metal atom of the metal complex is a metal cation capable of forming four coordinate complexes and/or six-coordinate complexes, said cation being chosen from cations of iron, cations of ruthenium, cations of osmium, cations of technetium, cations of rhodium, and mixtures of two or more of the foregoing cations.

As noted, in one embodiment of the present invention, the first ligand has structure I: 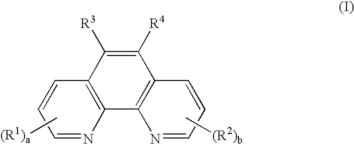
wherein a and b are independently integers from 0 to 3; R¹ and R² are independently at each occurrence a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical; R³ and R⁴ are independently a C₁-C₂₀ aliphatic radical, a C₃-C₄₀ aromatic radical, or a C₃-C₄₀ cycloaliphatic radical, wherein at least one of R³ and R⁴ comprises a nitrogen atom, or R³ and R⁴ together form a cycloaliphatic or aromatic radical comprising at least one nitrogen atom. Some illustrative examples of structure I include, but are not limited to, structures II, II and IV; 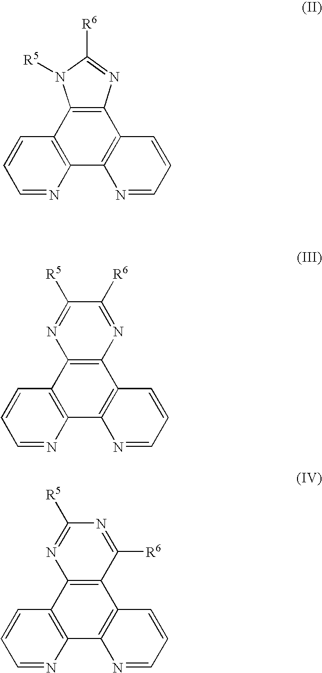
wherein R⁵ and R⁶ are independently a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical.

In one embodiment of the present invention, the first ligand has structure II. Structure II exemplifies structure I where a and b are equal to 0 and R³ and R⁴ together form a 3-R⁵-substituted, 2-R⁶-substituted imidazole ring. Thus by way of example, in one embodiment of the present invention, structure II may be 3-i-propyl-2-(4′-nitro)phenylimidazo[4,5-f]1,10-phenanthroline where R⁵ is an isopropyl radical and R⁶ is a 4-nitrophenyl radical. In another embodiment of the present invention, structure II may be 3-ethyl-2-phenylimidazo[4,5-f]1,10-phenanthroline where R⁵ is an ethyl radical and R⁶ is a phenyl radical.

The second ligand comprises at least one acidic group, and at least two coordinative nitrogen atoms capable of simultaneous binding to the metal atom. In dye sensitized solar cell applications, for example, the acidic groups may serve as anchoring groups to the surface of a semiconductor layer and thus improve the adsorbing efficiency of the metal complex dye. Suitable examples of acidic groups that can serve as anchoring groups include but are not limited to carboxylic acid groups, sulfonic acid groups, phosphonic acid groups, sulfinic acid groups, boronic acid groups, their salts and mixtures thereof. The preferred anchoring groups for dyes used in solar cells are carboxylic or phosphonic acid groups, because they are thought to interact strongly with the surface hydroxyl groups of the semiconductor surface. Furthermore, the coordinative nitrogen atoms of the second ligand are comprised within at least one aromatic radical.

In one embodiment of the present invention, the second ligand has structure V 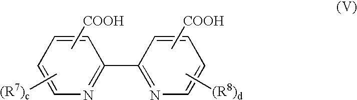
wherein c and d are independently integers from 0 to 3; and R⁷ and R⁸ are independently at each occurrence a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical. Some illustrative examples of second ligands having structure V include, but are not limited to, structures VI, VII and VIII.

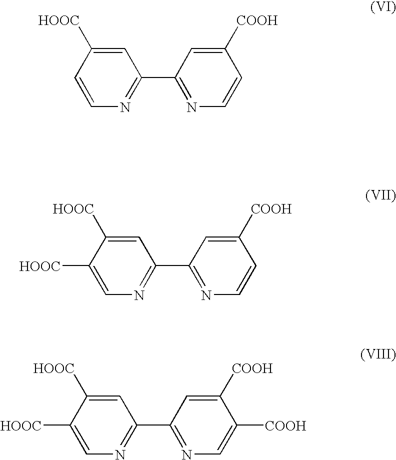

In one embodiment of the present invention, the second ligand is 2,2′-bipyridine-4,4′-dicarboxylic acid having structure VI. Structure VI exemplifies structure IV where c and d are equal to 0 and the carboxylic acid groups are located at the 4- and 4′-positions of the 2,2′-bipyridine nucleus. The presence of the anchoring carboxylic acid groups at the 4- and 4′-positions of the 2,2′-bipyridyl nucleus of the second ligand is believed to enable the metal complex dye composition to self-organize on the semiconductor surface and to promote electronic coupling of the donor levels of the dye with the acceptor levels of the semiconductor.

The metal complex in the composition may be present as a monolayer or as a multilayer. For example, in one self-organizing scenario a metal complex comprising ligands II and VI binds to a TiO₂ semiconductor surface via the carboxylic acid groups of ligand VI, and thereafter a second molecule of the same metal complex forms at least one hydrogen bond with at least one of the imidazole ring nitrogens of the metal complex linked to the surface of the TiO2. Thus, a double layer of the metal complex dye may become bound to the surface of the TiO₂ semiconductor, the first layer of metal complex dye being bound to the surface of the TiO₂ semiconductor via the interaction of the TiO₂ with the carboxylic acid groups of the second ligand VI, and the second layer self assembling on the first layer via hydrogen bonding interactions between the exposed basic nitrogens of the first layer of the metal complex with the carboxylic acid groups of the metal complex of the second layer.

In one embodiment of the present invention, the metal complex may further include at least one third ligand comprising an anion chosen from halogen atoms, thiocyanate groups (⁻S—CN), isothiocyanate groups (⁻N═C═S), hydroxyl group, cyano groups (⁻CN), cyanate groups (⁻O—CN), isocyanate groups (⁻N═C═O), selenocyanate groups (⁻Se—CN), and isoselenocyanate groups (⁻N═C═Se). The third ligand is believed to aid in chelation of the metal atom of the metal complex dye and may allow a measure of control of the spectral response (e.g. λ-max and absorptivity) of the metal complex dye.

Various known methods may be used to prepare the metal complex dye compositions of the present invention once the requisite ligands have been synthesized. Thus, in one aspect, the present invention provides a method for the preparation of the one or more of the ligands used in the preparation of the metal complex dye compositions. In one embodiment, the first ligand is prepared by reacting a substituted-1,10-phenanthroline-5,6-dione with excess ammonium acetate, and a slight excess of an aldehyde (e.g. benzaldehyde) glacial acetic acid at reflux. After neutralization, the crude product can be recrystallized to obtain a purified first ligand, for example compound II wherein R⁵ is hydrogen and R⁶ is phenyl. The first ligand may be further transformed to provide additional first ligand derivatives. For example, compound II wherein R⁵ is hydrogen may be further reacted with excess sodium hydride and benzyl bromide in a polar aprotic solvent such as tetrahydrofuran to provide the corresponding N-benzyl derivative (i.e., R⁵=benzyl). This first ligand is reacted with 0.5 equivalents of a metal chloride complex in a solvent, followed by equivalent amount of a second ligand, for example a ligand having structure VI. The resultant complex may be further reacted with third ligand. In one embodiment the third ligand is an anionic species, such as thiocyanate. Typically a third ligand may be introduced into the metal complex by reacting a metal chloride complex in sequence with a first ligand, a second ligand, and lastly with an excess of a third ligand. The reaction product comprising the metal complex dye may be purified by conventional techniques such as crystallization, trituration, and/or chromatography.

In one embodiment of the present invention the metal complex dye comprises a ruthenium cation as the metal atom, a first ligand having structure II wherein R⁵ is hydrogen and R⁶ is a phenyl group, a second ligand 2,2′-bipyridine-4,4′-dicarboxylic acid, and two thiocyanate ligands, which is prepared as follows. The first ligand is produced by refluxing in glacial acetic acid 1,10-phenanthroline-5,6-dione with excess ammonium acetate, and a slight molar excess (relative to the phenanthroline dione) of benzaldehyde. After neutralization with concentrated aqueous ammonia, the crude product can be recrystallized to obtain the first ligand. This first ligand is then reacted with 0.5 equivalents of a dimeric ruthenium complex [RuCl₂(p-cymene)]₂ in dimethylformamide, followed by equivalent amount of 2,2′-bipyridine-4,4′-dicarboxylic acid, followed by treatment with excess of ammonium thiocyanate (NH₄NCS). The product may be purified by conventional techniques

By using another metal in place of ruthenium other metal complexes can be produced in the same manner. Various anionic third ligands may be introduced by using H₂O, NH₄CN, NH₄NCO, or NH₄SeCN in place of NH₄NCS (ammonium thiocyante) to produce additional varieties of metal complex dyes.

In the above reactions it is assumed that the reaction dynamics are controlled by sequential displacement of the weakly coordinating ligands by more strongly coordinating ligands. In one embodiment of the present invention the product mixture comprises two or more different metal complex dyes. For example, a metal complex represented by structure IX may be present in the product mixture comprising metal complex dye X. 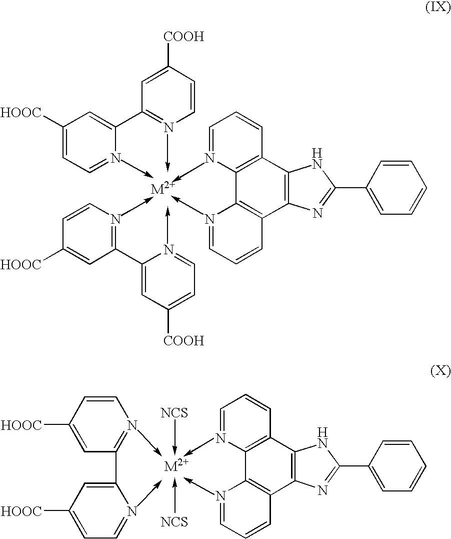
wherein in each of structures IX and X, M²⁺ is a metal cation selected from the group consisting cations of ruthenium, cations of osmium, cations of technetium, cations of rhodium, and mixtures thereof.

In further embodiment, the present invention provides a dye-sensitized electrode comprising a substrate having an electrically conductive surface, a semiconductor layer that is disposed on the electrically conductive surface, and a composition having at least one metal complex described above, disposed on the semiconductor surface.

In one embodiment, the substrate of the dye-sensitized electrode comprises at least one glass film. In an alternate embodiment the substrate comprises at least one polymeric material. Examples of suitable polymeric materials include but are not limited to polyacrylates, polycarbonates, polyesters, polysulfones, polyetherimides, silicones, epoxy resins, and silicone-functionalized epoxy resins. The substrate is selected so that it is substantially transparent, that is, a test sample of the substrate material having a thickness of about 0.5 micrometer allows approximately 80 percent of incident electromagnetic radiation having wavelength in the range from about 290 nm to about 1200 nm at an incident angle less than about 10 degrees to be transmitted through the sample.

At least one surface of the substrate is coated with a substantially transparent, electrically conductive material. Suitable materials that can be for coating are substantially transparent conductive oxides, such as indium tin oxide (ITO), tin oxide, indium oxide, zinc oxide, antimony oxide, and mixtures thereof. A substantially transparent layer, a thin film, or a mesh structure of metal such as silver, gold, platinum, titanium, aluminum, copper, steel, or nickel is also suitable.

The dye-sensitized electrode further comprises a semiconductor layer disposed in electrical contact with the electrically conductive material coated on the substrate. Suitable semiconductors are metal oxide semiconductors, such as oxides of the transition metals, and oxides of the elements of Group III, IV, V, and VI of the Periodic Table. Especially, oxides of titanium, zirconium, hafnium, strontium, zinc, indium, yttrium, lanthanum, vanadium, niobium, tantalum, chromium, molybdenum, tungsten, iron, nickel, silver or mixed oxides of these metals may be employed. Other suitable oxides include those having a perovskite structure such as SrTiO₃ or CaTiO₃. The semiconductor layer is coated by adsorption of the composition comprising the metal complex on the surface thereof. Preferably the metal complex is chemically bonded to the surface of the semiconductor layer.

In one embodiment, the present invention provides a solar cell comprising a dye-sensitized electrode as described above, a counter electrode, and an electrolyte in contact with the dye-sensitized electrode and the counter electrode.

The electrolyte can be, for example, a I⁻/I₃⁻ system, a Br⁻/Br₃⁻ system, or a quinone/hydroquinone system. The electrolyte can be liquid or solid. The solid electrolyte can be obtained by dispersing the electrolyte in a polymeric material. In the case of a liquid electrolyte, an electrochemical inert solvent such as acetonitrile, propylene carbonate or ethylene carbonate may be used.

Any electrically conductive material may be used as the counter electrode. Illustrative examples of suitable counter electrodes are a platinum electrode, a rhodium electrode, a ruthenium electrode or a carbon electrode.

The two electrodes and the electrolyte are arranged in a case or encapsulated within a resin in a way such that the dye-sensitized oxide semiconductor electrode is capable of being irradiated with electromagnetic radiation. When the semiconductor electrode is irradiated, an electric current is generated as a result of the electrical potential difference created during irradiation.

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

### EXAMPLES

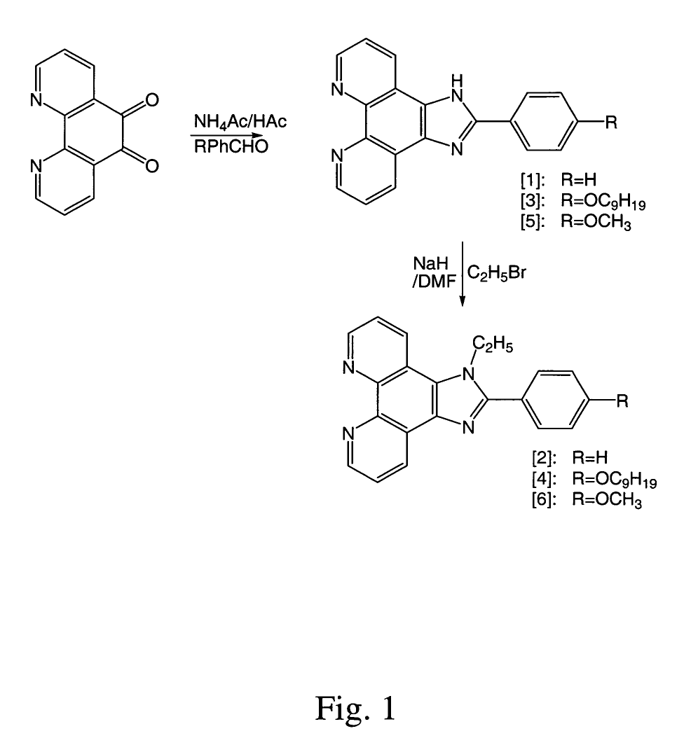

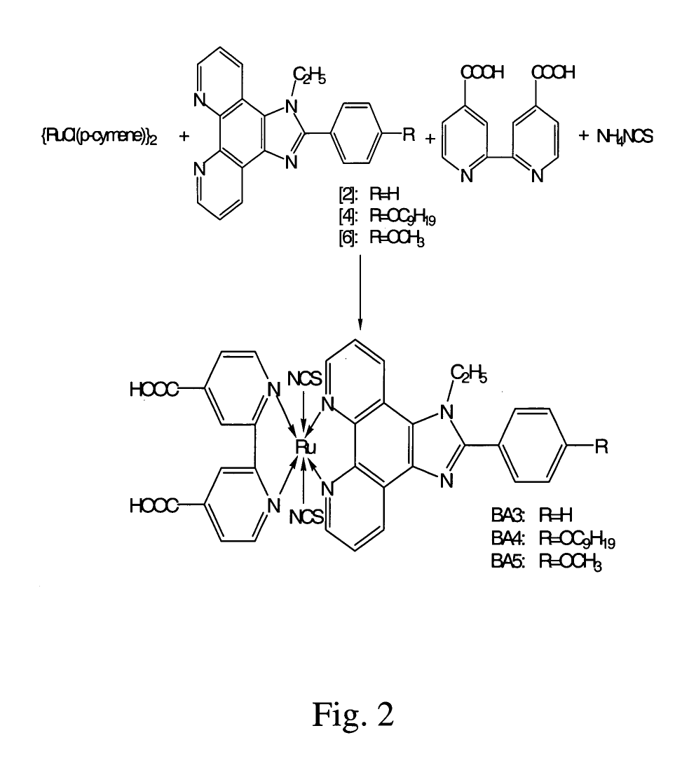

In the following examples 1,10-phenanthroline-5,6-dione, [RuCl₂(p-cymene)]₂, 2,2′-bipyridine-4,4′-dicarboxylic acid, benzaldehyde, 4′-nonoxybenzaldehyde, 4′-methoxybenzaldehyde, and ammonium thiocyanate (NH4NCS) were obtained from Acros Co. Reaction products were analyzed using ¹H NMR Spectroscopy. FIGS. 1 and 2 illustrate the reaction scheme for Examples 1, 2 and 3.

### Example 1

### Synthesis of BA3 (cis-dithiocyanato-2,2′-bipyridyl-4,4′-dicarboxylate-3-ethyl-2-phenylimidazo[4,5-f]1,10-phenanthroline ruthenium(II) complex)

Synthesis of 2-phenylimidazo[4,5-f]1,10-phenanthroline[1]: A mixture of 1,10-phenanthroline-5,6-dione (5 mmol, 1.05 g), ammonium acetate (100 mmol, 7.2 g), benzaldehyde (6 mmol, 0.64 g) and glacial acetic acid (60 mL) was refluxed for about 2 h in a reaction flask and then cooled to room temperature. After neutralization with concentrated aqueous ammonia, the precipitates were collected and washed with water. The crude product 2-phenylimidazo[4,5-f]1,10-phenanthroline[1] was recrystallized from ethanol. The yield of the resulting purified product was 70%. The structure of the purified product was confirmed by ¹H NMR.

Synthesis of 3-ethyl-2-phenylimidazo[4,5-f]1,10-phenanthroline[2]: 1 equiv of 2-phenylimidazo[4,5-f]1,10-phenanthroline[1] was dissolved in anhydrous DMF and an excess of NaH was added. After the elution of H₂ had ceased, the mixture was stirred at 100° C. for further 30 min, and then 1-bromoethane (2 equiv) was added. After stirring for 24 h at 100° C., the reaction was stopped and the mixture was filtered. From the resulting filtrate, the crude product was isolated collected by concentration under vacuum followed by column chromatography on silica gel. The yield of the resulting purified product 3-ethyl-2-phenylimidazo[4,5-f]1,10-phenanthroline [2] was 45%. The structure of the purified product was confirmed by ¹H-NMR.

Synthesis of BA3: [RuCl₂(p-cymene)]₂ (0.16 mmol, 0.1 g) was dissolved in DMF (40 mL) and 3-ethyl-2-phenylimidazo[4,5-f]1,10-phenanthroline[2](0.32 mmol) was added. The reaction mixture was heated to 80° C. under argon for 5 h with constant stirring. 2,2′-bipyridine-4,4′-dicarboxylic acid (0.32 mmol, 0.08 g) was then added to the reaction flask and the reaction mixture was refluxed for further 4 h. Finally, excess of NH4NCS (13 mmol, 0.99 g) was added to the reaction mixture and the resulting mixture was refluxed for another 4 h. After completion of the reaction, the solvent was removed by distillation under vacuum. Water was added to the flask and the insoluble solid product was collected by filtration. The resulting product was washed with distilled water and diethyl ether, and then dried. The yield of the resulting dark product was ˜70%. The crude product was dissolved in the mixture of Bu₄NOH/methanol and was purified on Sephadex LH-20. The main red band was collected and concentrated. The residue was neutralized by 0.1M HNO₃. Then the dark red precipitate was collected after addition of distilled water. The solid was washed with water and dried. The final yield was 50%.

### Example 2

### Synthesis of BA4 (cis-dithiocyanato-2,2′-bipyridyl-4,4′-dicarboxylate-3-ethyl-2-(4′-nonoxyphenyl)imidazo[4,5-f]1,10-phenanthroline ruthenium(II) complex)

Synthesis of 2-(4′-nonoxy)phenylimidazo[4,5-f]1,10-phenanthroline[3]: A mixture of 1,10-phenanthroline-5,6-dione (5 mmol, 1.05 g), ammonium acetate (100 mmol, 7.2 g), 4′-nonoxybenzaldehyde (6 mmol) and glacial acetic acid (60 mL) was refluxed for about 2 h in a reaction flask and then cooled to room temperature. After neutralization with concentrated aqueous ammonia, the precipitates were collected and washed with water. The crude product was recrystallized from chloroform/ethanol (1:5). Yield of the resulting purified product was 73%. Structure of the purified product was confirmed by ¹H NMR.

Synthesis of 3-ethyl-2-(4′-nonoxy)(phenylimidazo[4,5-f]1,10-phenanthroline [4]: 1 equiv of 2-(4′-nonoxy)phenylimidazo[4,5-f]1,10-phenanthroline [3] was dissolved in anhydrous DMF and then excess of NaH was added which resulted in evolution of H₂. After the elution of H₂ had ceased, the mixture was stirred at 100° C. for further 30 min, and then 1-bromoethane (2 equiv) was added. After stirring for 24 h at 100° C., the reaction was stopped and the mixture was filtered. From the resulting filtrate, the crude product was collected by distillation under vacuum and purified by column chromatography on silica gel. Yield of the resulting purified product was 50%. Structure of the purified product was confirmed by¹H NMR.

Synthesis of BA4: [RuCl₂(p-cymene)]₂ (0.16 mmol, 0.1 g) was dissolved in DMF (40 mL) and 3-ethyl-2-(4′-nonoxy)(phenylimidazo[4,5-f]1,10-phenanthroline[4](0.32 mmol) was added. The reaction mixture was heated to 80° C. under argon for 5 h with constant stirring. 2,2′-bipyridine-4,4′-dicarboxylic acid (0.32 mmol, 0.08 g) was then added to the reaction flask and the reaction mixture was refluxed for further 4 h. Finally, excess of NH₄NCS (13 mmol, 0.99 g) was added to the reaction mixture and the resulting mixture was refluxed for another 4 h. After completion of the reaction, the solvent was removed by distillation under vacuum. Water was added to the flask and the insoluble solid product was collected by filtration. The resulting product was washed with distilled water and diethyl ether, and then dried. Yield of the resulting dark product was 72%

### Example 3

### Synthesis of BA5 (cis-dithiocyanato-2,2′-bipyridyl-4,4′-dicarboxylate-3-ethyl-2-(4′-methoxyphenyl)imidazo[4,5-f]1,10-phenanthroline ruthenium(II) complex)

Synthesis of 2-(4′-methoxy)phenylimidazo[4,5-f]1,10-phenanthroline[5]: A mixture of 1,10-phenanthroline-5,6-dione (5 mmol, 1.05 g), ammonium acetate (100 mmol, 7.2 g), 4′-methoxybenzaldehyde (6 mmol) and glacial acetic acid (60 mL) was refluxed for about 2 h in a reaction flask and then cooled to room temperature. After neutralization with concentrated aqueous ammonia, the precipitates were collected and washed with water. The crude product was recrystallized from chloroform/ethanol (2:5 v:v). Yield of the resulting purified product was 75%. Structure of the purified product was confirmed by ¹H NMR.

Synthesis of 3-ethyl-2-(4′-methoxy)(phenylimidazo[4,5-f]1,10-phenanthroline [6]: 1 equiv of 2-(4′-methoxy)phenylimidazo[4,5-f]1,10-phenanthroline [5] was dissolved in anhydrous DMF and then excess of NaH was added which resulted in evolution of H₂. After the elution of H₂ had ceased, the mixture was stirred at 100° C. for further 30 min, and then 1-bromoethane (2 equiv) was added. After stirring for 24 h at 100° C., the reaction was stopped and the mixture was filtered. From the resulting filtrate, the crude product was collected by distillation under vacuum and purified by column chromatography on silica gel. Yield of the resulting purified product was 55%. Structure of the purified product was confirmed by ¹H NMR.

Synthesis of BA5: [RuCl₂(p-cymene)]₂ (0.16 mmol, 0.1 g) was dissolved in DMF (40 mL) and 3-ethyl-2-(4′-methoxy)phenylimidazo[4,5-f]1,10-phenanthroline (0.32 mmol) was added. The reaction mixture was heated to 80° C. under argon for 5 h with constant stirring. 2,2′-bipyridine-4,4′-dicarboxylic acid (0.32 mmol, 0.08 g) was then added to the reaction flask and the reaction mixture was refluxed for further 4 h. Finally, excess of NH₄NCS (13 mmol, 0.99 g) was added to the reaction mixture and the resulting mixture was refluxed for another 4 h. After completion of the reaction, the solvent was removed by distillation under vacuum. Water was added to the flask and the insoluble solid product was collected by filtration. The resulting product was washed with distilled water and diethyl ether, and then dried. Yield of the resulting dark product was 69%.

Cell Performance with BA3, BA4 and BA5

In the following examples, the titania used was Solaronix DSPW with a 92 mesh screen which was purchased from Solaronix (Switzerland). The standard dye, N3 was also obtained from Solaronix (Switzerland). Dyeing of cells were carried out in a Teflon box that held six plates with six 5 mm×50 mm cells per plate; 36 cells in all.

### Example 4

Dyeing of the titania surface was carried out using 0.3 mM dye solutions of BA3 in DMSO. About 85 mL of the dye solution was used to cover the cells in order to produce near saturated titania surfaces. X-ray fluorescence (XRF) was used determine the amount of dye loading on the titania surface. The Ru:Ti intensity ratios were assumed to be proportional to dye loading on the titania surface Dye-coated titania films were then made into cells and tested under 1 sun illumination using standard electrolyte (0.5M tetra-(n-propyl)ammonium iodide, 0.5M 4-tert-butylpyridine, 0.05M I₂, and 0.1M LiI in acetonitrile).

### Example 5

With the exception of replacing the 0.3 mM dye solution of BA3 in DMSO with 0.3 mM solution of BA4 in DMSO, dyeing and characterization of cells were carried out in the same manner as example 4.

### Example 6

With the exception of replacing the 0.3 mM dye solution of BA3 in DMSO with 0.3 mM solution of BA5 in DMSO, dyeing and characterization of cells were carried out in the same manner as example 4.

### Example 7

With the exception of replacing the 0.3 mM dye solution of BA3 with 0.3 mM solution of N3 in ethanol, dyeing and characterization of cells were carried out in the same manner as example 4.

The results from the above experiments are shown in Table 1 and Table 2. Table 1 shows dye loading on titania surface for BA3, BA4 and BA5 relative to a standard dye N3. The three dyes showed different dye loading efficiencies with BA3 showing equivalent dye loading as N3. BA4 showed about 85% loading on the titania surface when compared to N3, while BA5 showed 73% loading. Table 2 shows the solar cell results obtained using dyes BA3, BA4, BA5 and N3, tested under 1 sun illumination using standard electrolyte. All the three dyes BA3, BA4 and BA5 showed generation of current, however, they exhibited different cell efficiencies.

TABLE 1
Dye loading by XRF

| Sample | Ru:Ti intensity | | Dye loading |
|---|---|---|---|
| Name | Ratio | stdev | Relative to N3 |
| BA3 | 0.0078 | 0.0003 | 0.99 |
| BA4 | 0.0067 | 0.0003 | 0.85 |
| BA5 | 0.0058 | 0.0001 | 0.73 |
| N3 | 0.0079 | 0.0001 | 1.00 |

TABLE 2
Cell Performance

| | Voc | Jsc | FF | Eff |
|---|---|---|---|---|
| N3 | | | | |
| Avg. | 0.652 | 10.9 | 0.630 | 4.47 |
| Stdev. | 0.007 | 0.36 | 0.008 | 0.12 |
| BA3 | | | | |
| Avg. | 0.534 | 4.4 | 0.592 | 1.38 |
| Stdev. | 0.003 | 0.09 | 0.028 | 0.08 |
| BA4 | | | | |
| Avg. | 0.577 | 7.6 | 0.604 | 2.66 |
| Stdev. | 0.012 | 0.19 | 0.047 | 0.30 |
| BA5 | | | | |
| Avg. | 0.598 | 8.5 | 0.574 | 2.92 |
| Stdev. | 0.003 | 0.19 | 0.018 | 0.11 |

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims.

1. A composition comprising at least one metal complex, said metal complex comprising:
(a) at least one metal atom;
(b) at least one first ligand having structure I 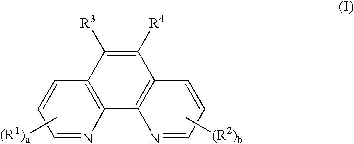
wherein a and b are independently integers from 0 to 3; R¹ and R² are independently at each occurrence a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical; R³ and R⁴ are independently a C₁-C₂₀ aliphatic radical, a C₃-C₄₀ aromatic radical, or a C₃-C₄₀ cycloaliphatic radical, wherein at least one of R³ and R⁴ comprises a nitrogen atom, or R³ and R⁴ together form a cycloaliphatic or aromatic radical, said cycloaliphatic or aromatic radical comprising at least one nitrogen atom; and
(c) at least one second ligand comprising at least one acidic group, and at least two coordinative nitrogen atoms capable of simultaneous binding to said metal atom.

2. A composition according to claim 1, wherein said metal atom is a metal cation chosen from cations of iron, cations of ruthenium, cations of osmium, cations of technetium, cations of rhodium, and mixtures thereof.

3. A composition according to claim 1 wherein said at least one acidic group is chosen from carboxylic acid groups, sulfonic acid groups, phosphonic acid groups, sulfinic acid groups, boronic acid groups, their salts, and mixtures thereof.

4. A composition according to claim 1 wherein said coordinative nitrogen atoms of said at least one second ligand are comprised within at least one aromatic radical.

5. A composition according to claim 1 wherein said at least one second ligand has structure V 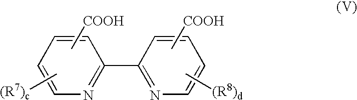
wherein c and d are independently integers from 0 to 3; and R⁷ and R⁸ are independently at each occurrence a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical.

6. A composition according to claim 1 further comprising at least one third ligand chosen from halogen atoms, thiocyanate groups, isothiocyantes, hydroxyl groups, cyano groups, isocyanate groups, isocyanide groups, selenocyante groups, and isoselenocyanate groups.

7. A composition comprising at least one metal complex, said metal complex comprising:
(a) at least one ruthenium cation;
(b) at least one first ligand having structure II 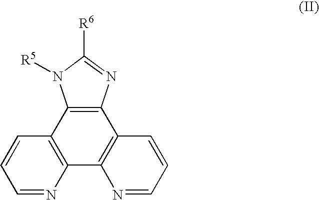
wherein R⁵ and R⁶ are independently a hydrogen atom, a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical;
(c) at least one second ligand having structure VI; and 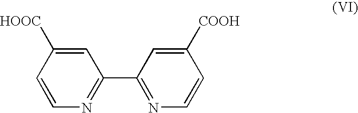
(d) at least one third ligand comprising a thiocyanate or an isothiocyante group.

8. A dye-sensitized electrode comprising:
(a) a substrate comprising an electrically conductive surface;
(b) a semiconductor layer disposed on the electrically conductive surface; and
(c) a composition comprising at least one metal complex, said metal complex comprising:
(i) at least one metal atom;
(ii) at least one first ligand having structure I 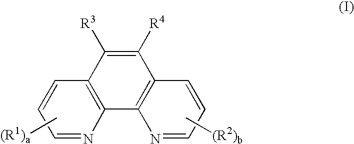
wherein a and b are independently integers from 0 to 3; R¹ and R² are independently at each occurrence a halogen atom, a nitro group, a cyano group, a carboxyl group, a hydroxyl group, a C₁-C₂₀ aliphatic radical, a C₃-C₄₀ aromatic radical, or a C₃-C₄₀ cycloaliphatic radical; R³ and R⁴ are independently a C₁-C₂₀ aliphatic radical, a C₃-C₄₀ aromatic radical, or a C₃-C₄₀ cycloaliphatic radical, wherein at least one of R³ and R⁴ comprises a nitrogen atom, or R³ and R⁴ together form a cycloaliphatic or aromatic radical comprising at least one nitrogen atom; and
(iii) at least one second ligand comprising at least one acidic group, and at least two coordinative nitrogen atoms capable of simultaneous binding to said metal atom.

9. A dye-sensitized electrode according to claim 8, wherein said metal atom is a metal cation chosen from cations of iron, cations of ruthenium, cations of osmium, cations of technetium, cations of rhodium, and mixtures thereof.

10. A dye-sensitized electrode according to claim 8, wherein said at least one acidic group is chosen from carboxylic acid groups, sulfonic acid groups, phosphonic acid groups, sulfinic acid groups, boronic acid groups, their salts and mixtures thereof.

11. A dye-sensitized electrode according to claim 8, wherein said at least one second ligand has structure V 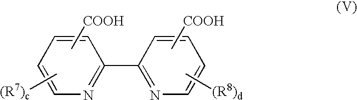
wherein c and d are independently integers from 0 to 3; R⁷ and R⁸ are independently at each occurrence a halogen, a nitro, a cyano, a carboxy, a hydroxyl, a C₁-C₂₀ aliphatic radical, a C₃-C₄₀ aromatic radical, or a C₃-C₄₀ cycloaliphatic radical.

12. A dye-sensitized electrode according to claim 8, wherein the said at least one metal complex further comprises at least one third ligand chosen from halogen atoms, thiocyanate groups, isothiocyanate groups hydroxyl groups, cyano groups, isocyanate groups, isocyanide groups, selenocyanate groups, and isoselenocyanate groups.

13. A dye-sensitized electrode comprising:
(a) a substrate comprising an electrically conductive surface;
(b) a TiO₂ layer disposed on the electrically conductive surface; and
(c) a composition comprising at least one metal complex, said metal complex comprising:
(i) at least one ruthenium cation;
(ii) at least one first ligand having structure II 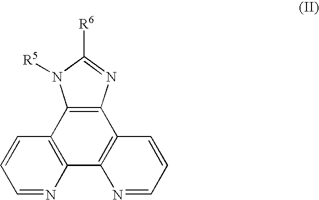
wherein R⁵ and R⁶ are independently a hydrogen atom, a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical;
(iii) at least one second ligand having structure VI; and 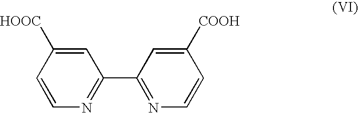
(iv) at least one third ligand comprising a thiocyanate or an isothiocyante group.

14. A solar cell comprising:
(a) a dye-sensitized electrode comprising a substrate comprising an electrically conductive surface; a semiconductor layer disposed on the electrically conductive surface; and a composition comprising at least one metal complex, said metal complex comprising:
(i) at least one metal atom;
(ii) at least one first ligand having structure I 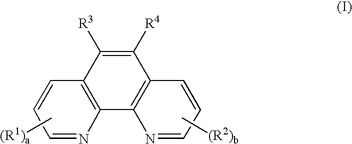
wherein a and b are independently integers from 0 to 3; R¹ and R² are independently at each occurrence a halogen atom, a nitro group, a cyano group, a carboxyl group, a hydroxyl group, a C₁-C₂₀ aliphatic radical, a C₃-C₄₀ aromatic radical, or a C₃-C₄₀ cycloaliphatic radical; R³ and R⁴ are independently a C₁-C₂₀ aliphatic radical, a C₃-C₄₀ aromatic radical, or a C₃-C₄₀ cycloaliphatic radical, wherein at least one of R³ and R⁴ comprises a nitrogen atom, or R³ and R⁴ together form a cycloaliphatic or aromatic radical comprising at least one nitrogen atom; and
(iii) at least one second ligand comprising at least one acidic group, and at least two coordinative nitrogen atoms capable of simultaneous binding to said metal atom;
(b) a counter electrode; and
(c) an electrolyte in contact with said dye-sensitized electrode and said counter electrode.

15. A solar cell according to claim 14, wherein said metal atom is a metal cation chosen from cations of iron, cations of ruthenium, cations of osmium, cations of technetium, cations of rhodium, and mixtures thereof.

16. A solar cell according to claim 14, wherein said at least one acidic group is chosen from carboxylic acid groups, sulfonic acid groups, phosphonic acid groups, sulfinic acid groups, boronic acid groups, their salts and mixtures thereof.

17. A solar cell according to claim 14, wherein said at least one second ligand has structure V 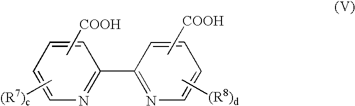
wherein c and d are independently integers from 0 to 3; R⁷ and R⁸ are independently at each occurrence a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical.

18. A solar cell according to claim 14, wherein the said at least one metal complex further comprises at least one third ligand chosen from halogen atoms, thiocyanate groups, isothiocyanate groups, hydroxyl groups, cyano groups, isocyanate groups, isocyanide groups, selenocyanate groups, and isoselenocyanate groups.

19. A solar cell comprising:
(a) a dye-sensitized electrode comprising a substrate comprising an electrically conductive surface; a TiO₂ layer disposed on the electrically conductive surface; and a composition comprising at least one metal complex, said metal complex comprising:
(i) at least one ruthenium cation;
(ii) at least one first ligand having structure II 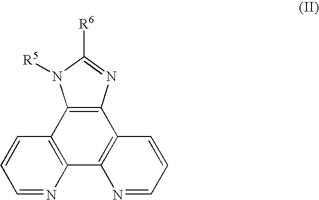
wherein R⁵ and R⁶ are independently a hydrogen atom, a halogen atom, a nitro group, a cyano group, a carboxy group, a hydroxyl group, a C₁-C₂₀ aliphatic radical, a C₃-C₄₀ aromatic radical, or a C₃-C₄₀ cycloaliphatic radical;
(iii) at least one second ligand having structure VI; and 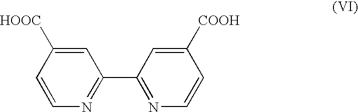
(iv) at least one third ligand comprising a thiocyanate or an isothiocyante group;
(b) a counter electrode; and
(c) an electrolyte contacting with said dye-sensitized electrode and said counter electrode.
